(19) United States
(12) Patent Application Publication
(10) Pub. No.: US 2016/0240590 A1
(43) Pub. Date: Aug. 18, 2016

(54) OLED PIXEL STRUCTURE

(71) Applicant: SHENZHEN CHINA STAR OPTOELECTRONICS TECHNOLOGY CO., LTD., Shenzhen, Guangdong (CN)

(72) Inventors: Yawei LIU, Shenzhen, Guangdong (CN); Yifan WANG, Shenzhen, Guangdong (CN)

(73) Assignee: Shenzhen China Star Optoelectronics Technology Co., Ltd., Shenzhen, Guangdong (CN)

(21) Appl. No.: 14/384,653

(22) PCT Filed: Aug. 14, 2014
(86) PCT No.: PCT/CN2014/084334

§ 371 Date: Sep. 11, 2014

(30) Foreign Application Priority Data
Jul. 9, 2014 (CN) 201410326558.9

(51) Int. Cl. H01L 27/32; H01L 51/52; H01L 51/00; H01L 51/50

(52) U.S. Cl. CPC H01L 27/326; H01L 27/3213; H01L 51/502; H01L 51/5056; H01L 51/5072; H01L 51/5206; H01L 51/5221; H01L 51/5088; H01L 51/001; H01L 51/0061; H01L 51/0072; H01L 51/0067; H01L 51/0085; H01L 51/0081; H01L 51/0035; H01L 51/0037; H01L 2251/301

(57) ABSTRACT

The present invention provides an OLED pixel structure, which comprises a red, a green and a blue sub-pixel; wherein the red sub-pixel has a red light emission layer, the green sub-pixel has a green light emission layer, and the blue sub-pixel has a blue light emission layer and a material of the blue light emission layer comprises a blue light quantum dot. Compared to the conventional technology, the blue sub-pixel in the OLED pixel structure of the present invention is more stable such that the whole OLED device could be more stable; the life time of the blue sub-pixel in the OLED pixel structure of the present invention is longer such that the life time of the OLED device could be longer; the efficiency of the blue light quantum dot is higher such that the driving voltage of the blue sub-pixel could be lowered properly. The OLED pixel structure could further comprise a white sub-pixel having a white light emission layer of which the material comprises inorganic quantum dot. The brightness of the OLED device can be improved by increasing the white sub-pixel.

### FIELD OF THE INVENTION

The present invention relates to a field of manufacturing an organic light emitting display, and more particularly to an OLED pixel structure.

### BACKGROUND OF THE INVENTION

The flat panel display has advantages of thin body, power saving, no radiation, etc., and is widely used. The flat panel display nowadays mainly comprises liquid crystal display (LCD) and organic light emitting display (OLED).

The OLED is regarded as a new application technique of next generation because of having the characteristics of self-emitting, no backlight being required, high contrast, thin film, wide viewing angle, fast response, being probably used in flexible panel, wide temperature range, and simpler structure and manufacturing process at the same time. From the view point of the molecular weight of the organic light emitting material, the OLED can be divided into oligomer organic light emitting display (OLED) and polymer light emitting display (PLED). The manufacturing processes of the organic light emitting display are greatly different because of the difference of the molecular weight. The OLED is mainly manufactured through the process of thermal evaporation, and the PLED is mainly manufactured through the process of spinning or ink-jet printing.

The OLED usually comprises: a substrate, an ITO transparent anode disposed on the substrate, a hole injection layer (HIL) disposed on the ITO transparent anode, a hole transport layer (HTL) disposed on the hole injection layer, an emission layer (EML) disposed on the hole transport layer, an electron transport layer (ETL) disposed on the emission layer, an electron injection layer (EIL) disposed on the electron transport layer, and a cathode disposed on the electron injection layer. In order to improve the efficiency, the emission layer is usually a guest-host doping system.

Semiconductor nanocrystals (NCs) is a semiconductor nano crystal grain having a size of 1-100 nm. Because the size of the NCs is smaller than the exciton Bohr radius of its material, a great quantum confinement effect is shown and the quasi-continuous energy band is developed into the discrete energy level similar to a molecular such that new material properties are shown, and, therefore, the NCs is so called as the quantum dots (QDs).

Because excited by external energy (light emitting, electrically emitting, cathode ray emitting, etc.), the electron is transited to excitation state from ground state such that the exciton could be formed by the electron in the excitation state and the hole. The electron is recombined with the hole and finally relaxed to the ground state. Extra energy is released through the procedure of recombination and relaxation, and photons could be emitted by radiative recombination.

Quantum dots light emitting diodes (QD-LEDs) are valuable and important to business application, and is extremely researched in the recent ten years. In fact, the QD-LEDs have many advantages over the organic light emitting diodes (OLEDs) in: (1) the line width of the light emitted by the quantum dots is about 20-30 nm such that, in contrast to the line width, which is bigger than 50 nm, of the light emitted by the organic light emitting diodes,the full width at half maximum (FWHM) of the light emitted by the quantum dots is thinner; (2) inorganic materials is more thermal stable than the organic materials, and the devices based on the inorganic materials will have a longer life time due to the excellent thermal stability since the main reason of device degradation is Joule heat generated when the device is under the circumstances of high brightness or high current density; (3) due to different life time of the organic materials of the red, green and blue primary colors, the color of the organic light emitting display will be changed as the time passes by; however, the three primary colors can be emitted by using quantum dots having different sizes composed of the same materials because of the quantum confinement effect, and the same materials behave similar degradation life time; (4) the infrared rays could be emitted by the quantum dots light emitting diodes while the wavelength of the light emitted by the organic materials are often less than 1 μm;(5) there's no spin-statisticallimitation on quantum dots, and the external quantum efficiency (EQE) could reach 100%. The EQE of the quantum dots light emitting diodes could be expressed as: η_{Ext}=ηᵣ*η_{INT}*η*η_{OUT}. Wherein, ηᵣ is the probability of forming exciton by the electron and the hole, η_{INT} is the internal quantum efficiency, i.e. the luminescence quantum yield (PLQY), η is the probability of radiation transition, and the η_{OUT} is the external coupling efficiency. The ηᵣ of the organic fluorescent dye is limited to 25%, wherein the forming ratio of the single state and the triplet state is 1:3 and light is emitted only by recombination of exciton with single state. However, the ηᵣ of the organic phosphorescent material is greater than 25% because of the spin-orbital coupling. It is noted that, the organic phosphorescent material degrades the host material. The _{iouT} of the flat light emitting device is about 20%, and the external coupling efficiency could be increased by using microcavity structure. The η_{INT} of the quantum dots light emitting diodes could be 100%, and when the electron and the hole has adaptive energy level, the ηᵣ thereof could be 100% as well.

The quantum dots light emitting diodes could be divided into organic-inorganic hybridization devices and all-inorganic devices. The former could have high luminance and could be soft manufactured while the latter has advantage of device stability.

There are several technique solutions to colorize the organic light emitting diodes. The first one is emitting RGB three primary color, which is represented by SAMSUNG and is only adaptive to the oligomer organic material that is easily sublimated; the advantage of this technology is that the process is easy, matured, and convenient for operation, however, the production capacity is low and the cost is high because high precision mask and alignment is required when manufacturing display panels with high resolution. The second one is the technology of using white light with RGB filters, which is represented by LG; the production cost is lowered because the CF technology of the liquid crystal display (LCD) can be used, no more mask alignment is needed, and the procedure of evaporation is greatly simplified, such that the organic light emitting diodes with big size and high resolution could be manufactured. However, a high performance white light material is needed because only about 30% of light could penetrate the filter due to the high light energy absorption of the filters, otherwise the efficiency of the device is low. The technology is generally used in oligomer organic light emitting display panel. The third one is using blue-light organic light emitting diode with green and red color conversion method (CCM) to realize color displaying. Because the manufacturing technology the same as the color filter could be used therein, the pixel density and yield rate could be improved when compared with the RGB colorization. The technology is developed by Idemitsu Kosan and Fuji Electric Co., Ltd.

For the first colorization technology solution, i.e. emitting RGB three primary color, the life time, efficiency and stability is lowered due to the poor efficiency, life time and stability of the blue-light organic material in the OLED layer nowadays. Therefore, there is an urge to solve the technical problem.

### SUMMARY OF THE INVENTION

One object of the present invention is to provide an OLED pixel structure such that the life time, efficiency, stability and brightness of the OLED having the pixel structure could be improved obviously while compared with the conventional OLED.

To achieve the above mentioned object, the present invention provides an OLED pixel structure. An OLED pixel structure comprises: a red, a green and a blue sub-pixel; wherein the red sub-pixel has a red light emission layer, the green sub-pixel has a green light emission layer, and the blue sub-pixel has a blue light emission layer, and the OLED pixel structure is characterized in that a material of the blue light emission layer comprises a blue light quantum dot.

A white sub-pixel is further comprised, and the white sub-pixel has a white light emission layer.

The material of the white light emission layer comprises a plurality of inorganic quantum dots, the inorganic quantum dots are a plurality of white light quantum dots, or the inorganic quantum dots are combinations of a red light quantum dot, a green light quantum dot and the blue light quantum dot, or the inorganic quantum dots are combinations of the blue light quantum dot and a yellow light quantum dot.

The material of the white light emission layer further comprises white light organic host material.

The white light quantum dots are quantum dots of II˜VI families comprising CdSe, CdS, CdTe, CdMnS, ZnSe or ZnMnSe, the blue light quantum dot is ZnCdS, CdSe/ZnS or nano-SiN₄, the green light quantum dot is CdSe/ZnS or ZnSe: Cu^{2|}, the red light quantum dot is CdSe/CdS/ZnS, the yellow light quantum dot is CdSe/CdS/ZnS, or ZnS: Mn²⁺.

the material of the blue light emission layer further comprises a blue light organic host material, and the blue light organic host material, a particle of the blue light quantum dot, and a solvent are mixed, and then coated and volatized to remove the solvent and obtain the blue light quantum dot; the solvent is chloroform, toluene, chlorobenzene, or methanol.

The blue light organic host material is TCTA or TRZ.

The blue light quantum dot, a surface coating reagent and a solvent are mixed, and then coated and volatizedto remove the solvent and obtain the blue light quantum dot; wherein the surface coating reagent comprises stearic acid, trioctylphosphine oxide, or polymethyl methacrylate, the solvent is chloroform, toluene, chlorobenzene, or methanol.

The blue light quantum dot is ZnCdS, CdSe/ZnS, or nano-SiN₄.

The red light emission layer is formed by a red light organic light emitting material, which is Ir(piq)₃; the green light emission layer is formed by a green light organic light emitting material, which is Ir(ppy)₃.

The OLED pixel structure further comprises a substrate and a covering layer sealing-connected to the substrate; the red, green and blue sub-pixel are set on the substrate respectively and are covered by the covering layer; the material of the substrate and the covering layer is glass or soft material, and at least one of the substrate and the covering layer is pervious to light; the red sub-pixel comprises: an anode disposed on the substrate, a thin film transistor disposed on the anode, a hole injection layer disposed on the thin film transistor, a hole transport layer disposed on the hole injection layer, the red light emission layer disposed on the hole transport layer, an electron transport layer disposed on the red light emission layer, and a cathode disposed on the electron transport layer; the green sub-pixel comprises: the anode disposed on the substrate, the thin film transistor disposed on the anode, the hole injection layer disposed on the thin film transistor, the hole transport layer disposed on the hole injection layer, the green light emission layer disposed on the hole transport layer, the electron transport layer disposed on the green light emission layer, and the cathode disposed on the electron transport layer; the blue sub-pixel comprises: the anode disposed on the substrate, the thin film transistor disposed on the anode, the hole injection layer disposed on the thin film transistor, the hole transport layer disposed on the hole injection layer, the blue light emission layer disposed on the hole transport layer, the electron transport layer disposed on the green light emission layer, and the cathode disposed on the electron transport layer; the material of the electron transport layer is 8-hydroxyquinoline aluminum salt, the material of the hole transport layer is polytriphenylamine, and the material of the hole injection layer is PEDOT.

The OLED pixel structure further comprises a substrate and a covering layer sealing-connected to the substrate; the red, green, blue and white sub-pixel are set on the substrate respectively and are covered by the covering layer; the white sub-pixel comprises: an anode disposed on the substrate, a thin film transistor disposed on the anode, a hole injection layer disposed on the thin film transistor, a hole transport layer disposed on the hole injection layer, the white light emission layer disposed on the hole transport layer, an electron transport layer disposed on the white light emission layer, and a cathode disposed on the electron transport layer; the material of the electron transport layer is 8-hydroxyquinoline aluminum salt, the material of the hole transport layer is polytriphenylamine, and the material of the hole injection layer is PEDOT.

The red light emission layer and the green light emission layer are manufactured by vacuum evaporation and formed after forming the blue light emission layer.

The present invention further provides an OLED pixel structure, which comprises a red, a green and a blue sub-pixel; wherein the red sub-pixel has a red light emission layer, the green sub-pixel has a green light emission layer, and the blue sub-pixel has a blue light emission layer and a material of the blue light emission layer comprises a blue light quantum dot;

wherein the material of the blue light emission layer further comprises a blue light organic host material, and the blue light organic host material, a particle of the blue light quantum dot, and a solvent are mixed, and then coated and volatizedto remove the solvent and obtain the blue light quantum dot; the solvent is chloroform, toluene, chlorobenzene, or methanol;

wherein the blue light organic host material is TCTA or TRZ;

wherein the blue light quantum dot, a surface coating reagent and a solvent are mixed, and then coated and volatizedto remove the solvent and obtain the blue light quantum dot; wherein the surface coating reagent comprises stearic acid, trioctylphosphine oxide, or polymethyl methacrylate, the solvent is chloroform, toluene, chlorobenzene, or methanol;

wherein the blue light quantum dot is ZnCdS, CdSe/ZnS, or nano-SiN₄;

wherein the red light emission layer is formed by a red light organic light emitting material, which is Ir(piq)₃; the green light emission layer is formed by a green light organic light emitting material, which is Ir(_{PPY})₃;

wherein the OLED pixel structure further comprises a substrate and a covering layer sealing-connected to the substrate; the red, green and blue sub-pixel are set on the substrate respectively and are covered by the covering layer; the material of the substrate and the covering layer is glass or soft material, and at least one of the substrate and the covering layer is pervious to light; the red sub-pixel comprises: an anode disposed on the substrate, a thin film transistor disposed on the anode, a hole injection layer disposed on the thin film transistor, a hole transport layer disposed on the hole injection layer, the red light emission layer disposed on the hole transport layer, an electron transport layer disposed on the red light emission layer, and a cathode disposed on the electron transport layer; the green sub-pixel comprises: the anode disposed on the substrate, the thin film transistor disposed on the anode, the hole injection layer disposed on the thin film transistor, the hole transport layer disposed on the hole injection layer, the green light emission layer disposed on the hole transport layer, the electron transport layer disposed on the green light emission layer, and the cathode disposed on the electron transport layer; the blue sub-pixel comprises: the anode disposed on the substrate, the thin film transistor disposed on the anode, the hole injection layer disposed on the thin film transistor, the hole transport layer disposed on the hole injection layer, the blue light emission layer disposed on the hole transport layer, the electron transport layer disposed on the green light emission layer, and the cathode disposed on the electron transport layer; the material of the electron transport layer is 8-hydroxyquinoline aluminum salt, the material of the hole transport layer is polytriphenylamine, and the material of the hole injection layer is PEDOT;

wherein the red light emission layer and the green light emission layer are manufactured by vacuum evaporation and formed after forming the blue light emission layer.

The beneficial effect of the present invention is that: by using blue light quantum dot as the material of the blue light emission layer of the blue sub-pixel, the OLED pixel structure makes the blue sub-pixel to be more stable and have longer life time such that the whole OLED device is more stable and has longer life time. At the same time, the driving voltage of the blue sub-pixel could be lowered properly because the efficiency of the blue light quantum dot is higher. The OLED pixel structure could further comprise a white sub-pixel having a white light emission layer of which the material comprises inorganic quantum dot. The brightness of the OLED device can be improved by increasing the white sub-pixel.

Please refer to the following detailed description and drawings relating to the present invention in order to further understand the feature and technical content of the present invention. However, the drawings are only for reference and explaining but not for limiting the present invention.

### BRIEF DESCRIPTION OF THE DRAWINGS

The technical solution and other beneficial effect can be easily known by describing the concrete embodiment in detail with the attached drawings as follows.

In the drawings:

FIG. 1 is a structural schematic diagram of the OLED pixel structure according to the first embodiment of the present invention.

FIG. 2 is a planar schematic diagram of the OLED pixel structure according to the first embodiment of the present invention.

FIG. 3 is a schematic diagram of the display panel in which the pixel structure shown in FIG. 2 is applied.

FIG. 4 is another schematic diagram of the display panel in which the pixel structure shown in FIG. 2 is applied.

FIG. 5 is a structural schematic diagram of the TFT driving circuit of the pixel structure shown in FIG. 2.

FIG. 6 is a structural schematic diagram of the OLED pixel structure according to the second embodiment of the present invention.

FIG. 7 is a planar schematic diagram of the OLED pixel structure according to the second embodiment of the present invention.

FIG. 8 is a structural schematic diagram of the display panel in which the pixel structure shown in FIG. 7 is applied.

FIG. 9 is a structural schematic diagram of the TFT driving circuit of the pixel structure shown in FIG. 7.

FIG. 10 is a planar schematic diagram of the OLED pixel structure according to the third embodiment of the present invention.

FIG. 11 is a structural schematic diagram of the display panel in which the pixel structure shown in FIG. 10 is applied.

### DETAILED DESCRIPTION OF PREFERRED EMBODIMENTS

In order to further describe the technical solution and the effect of the present invention, the preferred embodiments and drawings are combined to make a detail description as below.

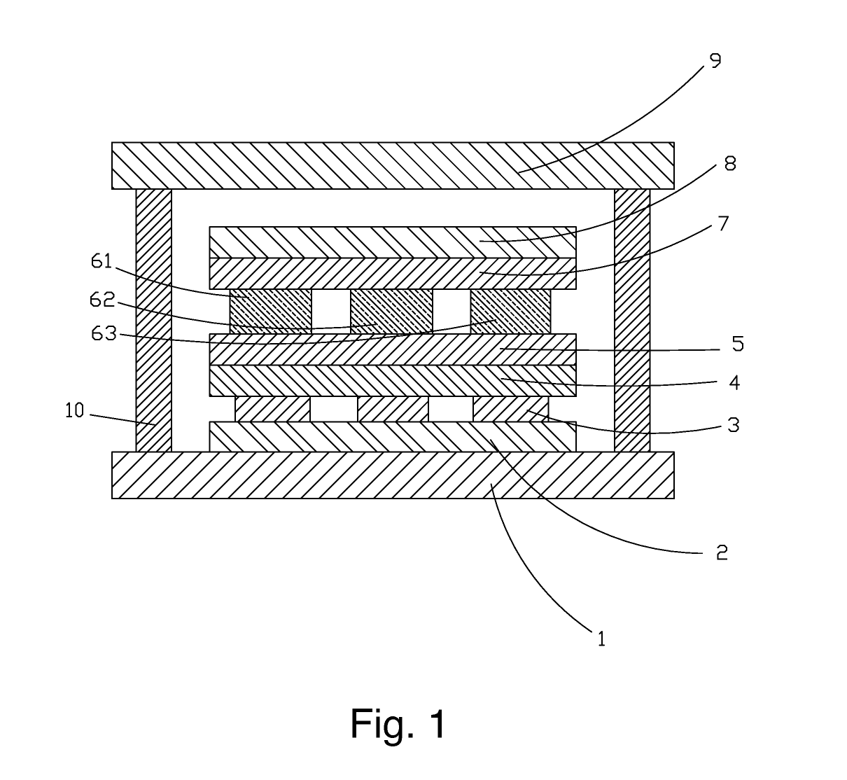

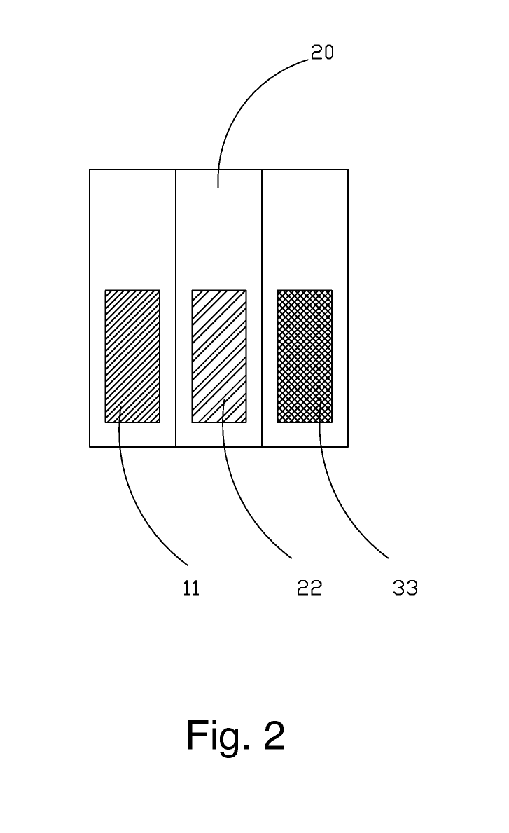

Please refer to FIGS. 1-2, which are the first embodiment of the present invention. In the embodiment, the present invention provides an OLED pixel structure comprising: a red, a green and a blue sub-pixel 11, 22, and 33. The red sub-pixel 11 has a red light emission layer 63, the green sub-pixel 22 has a green light emission layer 62, and the blue sub-pixel 33 has a blue light emission layer 61, of which the material comprises a blue light quantum dot.

The blue light quantum dot is ZnCdS, CdSe/ZnS, or nano-SiN₄.

When the blue light emission layer 61 is purely the blue light quantum dots, the method of manufacturing the blue light quantum dots is: mixing the blue light quantum dot, a surface coating reagent and a solvent, and then coating and volatizing to remove the solvent and obtain the blue light quantum dot. The surface coating reagent comprises stearic acid, trioctylphosphine oxide, or polymethyl methacrylate, and the solvent is chloroform, toluene, chlorobenzene, or methanol.

The material of the blue light emission layer 61 could further comprise a blue light organic host material, and, at this time,the method of manufacturing the blue light quantum dots is: mixing the blue light organic host material, a particle of the blue light quantum dot, and a solvent, and then coating and volatizing to remove the solvent and obtain the blue light quantum dot. The solvent is chloroform, toluene, chlorobenzene, or methanol.

The blue light organic host material is TCTA (4,4′,4″-Tris(carbazol-9-yl)-triphenylamine) or TRZ (2,4,6-Tri(9H-carbazol-9-yl)-1,3,5-triazine).

The structure of the compound TCTA is as follows:

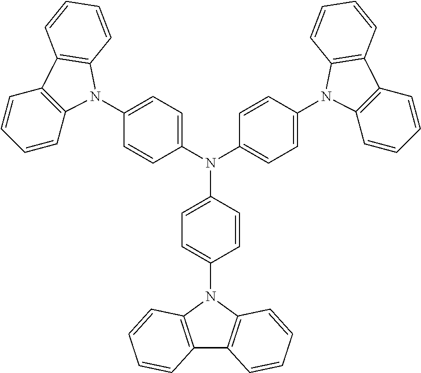 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

The structure of the compound TRZ is as follows:

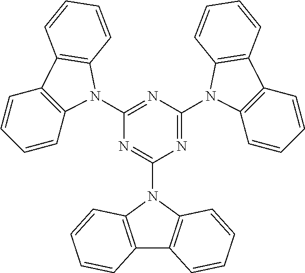 [SMILES: c1ccc2c(c1)c1ccccc1n2-c1nc(-n2c3ccccc3c3ccccc32)nc(-n2c3ccccc3c3ccccc32)n1]

Both the organic host material and the surface coating reagent have a function to prevent the inorganic quantum dots from being aggregated and oxidized. Because the inorganic quantum dots are nano-particles and are zero dimension materials. The surface activity is great and aggregation is occurred easily such that oxidization occurs and fluorescence is quenched.

The red light emission layer is formed by a red light organic light emitting material, which is Ir(piq)₃, and the green light emission layer is formed by a green light organic light emitting material, which is Ir(ppy)₃.

The structure of the Ir(piq)₃ is:

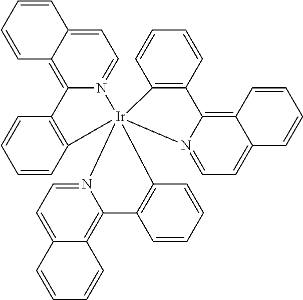

The structure of the Ir(ppy)₃ is:

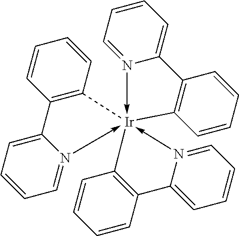

The red light emission layer 63 and the green light emission layer 62 are manufactured by vacuum evaporation and formed after forming the blue light emission layer 61.

The OLED pixel structure 20 of the present invention further comprises a substrate 1 and a covering layer 9 sealing-connected to the substrate 1; the red, green and blue sub-pixel 11, 22 and 33 are set on the substrate 1 respectively and are covered by the covering layer 9; the material of the substrate 1 and the covering layer 9 is glass or soft material, and at least one of the substrate 1 and the covering layer 9 is pervious to light; the red sub-pixel 11 comprises: an anode 2 disposed on the substrate 1, a thin film transistor 3 on the anode 2, a hole injection layer 4 disposed on the thin film transistor 3, a hole transport layer 5, disposed on the hole injection layer 4, the red light emission layer 63 disposed on the hole transport layer 5, an electron transport layer 7, disposed on the red light emission layer 63, and a cathode 8 disposed on the electron transport layer 7; the green sub-pixel 22 comprises: the anode 2 disposed on the substrate 1, the thin film transistor 3 on the anode 2, the hole injection layer 4 disposed on the thin film transistor 3, the hole transport layer 5, disposed on the hole injection layer 4, the green light emission layer 62 disposed on the hole transport layer 5, the electron transport layer 7, disposed on the green light emission layer 62, and the cathode 8 disposed on the electron transport layer 7; the blue sub-pixel 33 comprises: the anode 2 disposed on the substrate 1, the thin film transistor 3 on the anode 2, the hole injection layer 4 disposed on the thin film transistor 3, the hole transport layer 5, disposed on the hole injection layer 4, the blue light emission layer 61 disposed on the hole transport layer 5, the electron transport layer 7, disposed on the green light emission layer 61, and the cathode 8 disposed on the electron transport layer 7; the material of the electron transport layer 7, is 8-hydroxyquinoline aluminum salt, the material of the hole transport layer 5, is polytriphenylamine, and the material of the hole injection layer 4 is PEDOT (poly(3,4-ethylenedioxythiophene)).

The substrate 1 and the covering layer 9 are adhered to each other by sealing glue 10 in order to seal and protect the internal electronic devices.

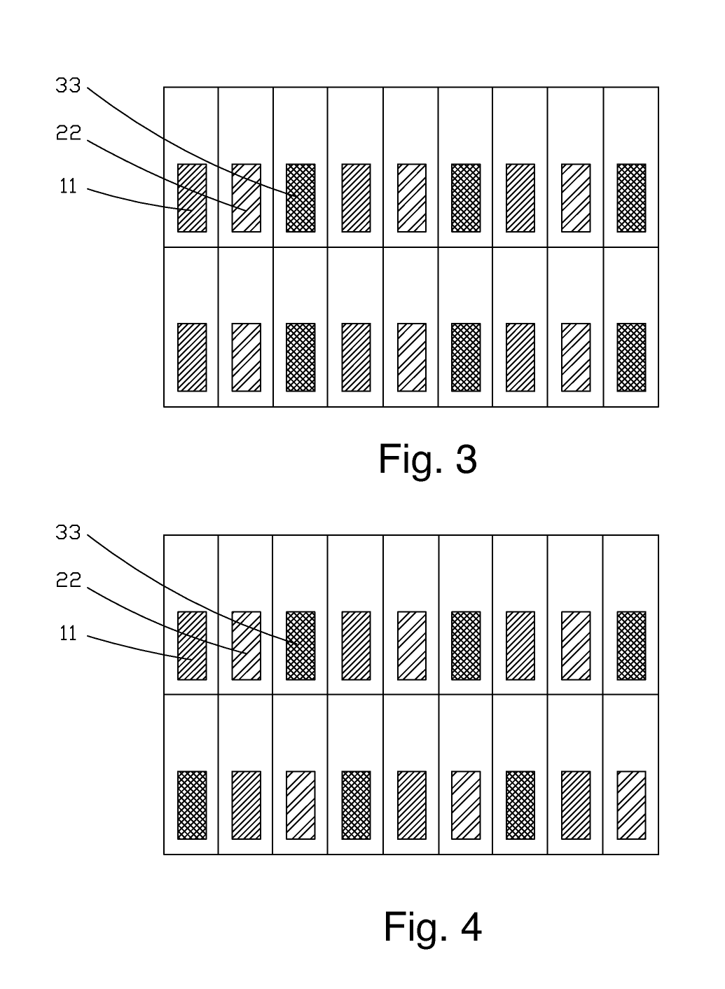

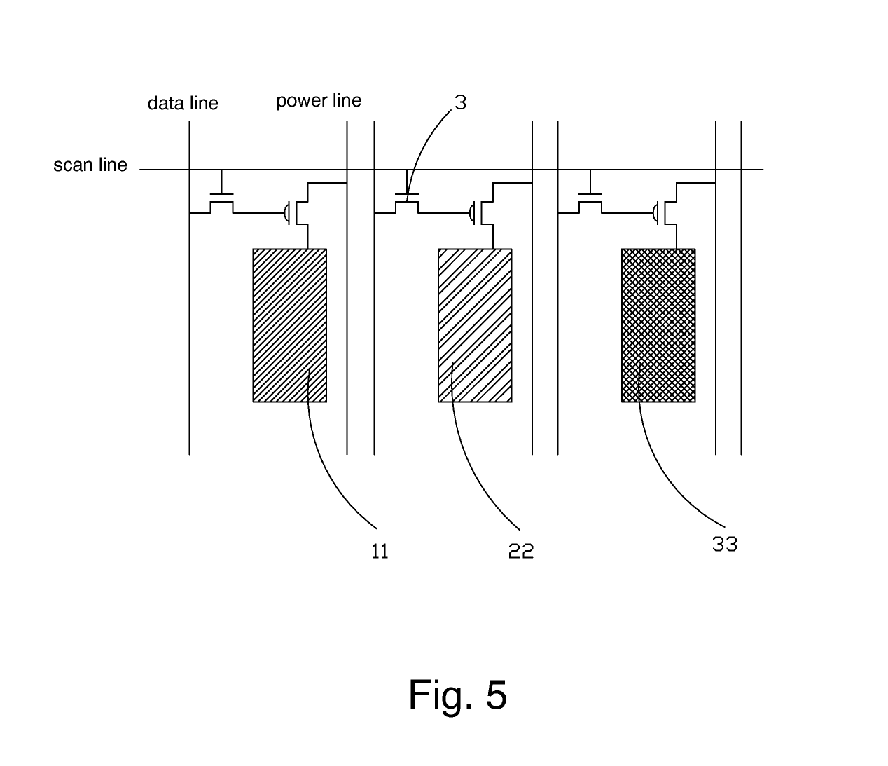

Please refer to FIG. 3 and FIG. 4, which are structural schematic diagrams of the display panel in which the pixel structure according to the first embodiment of the present invention is applied. As shown in FIG. 5, the red sub-pixel 11, green sub-pixel 22 and blue sub-pixel 33 are driven by the TFT 3.

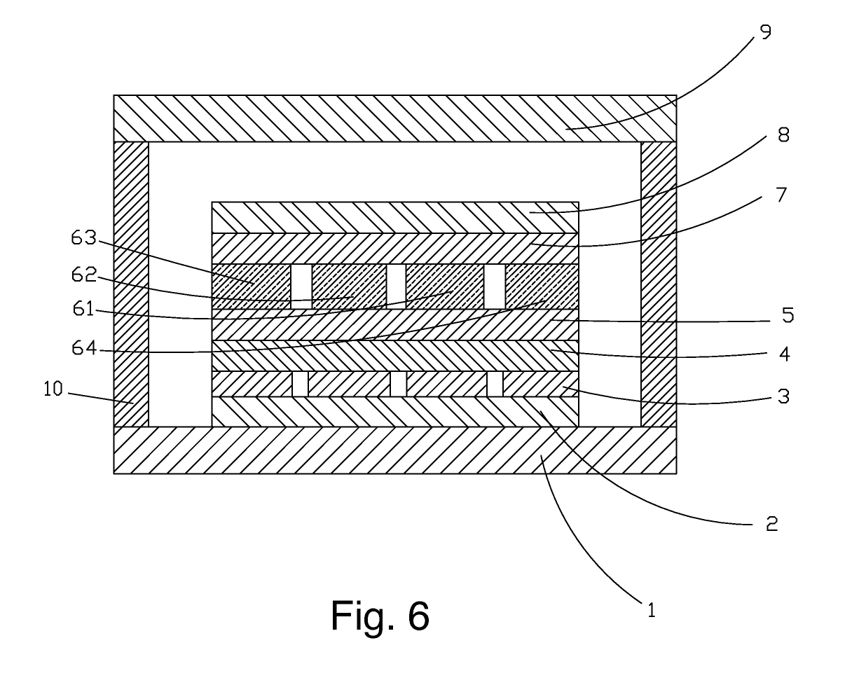

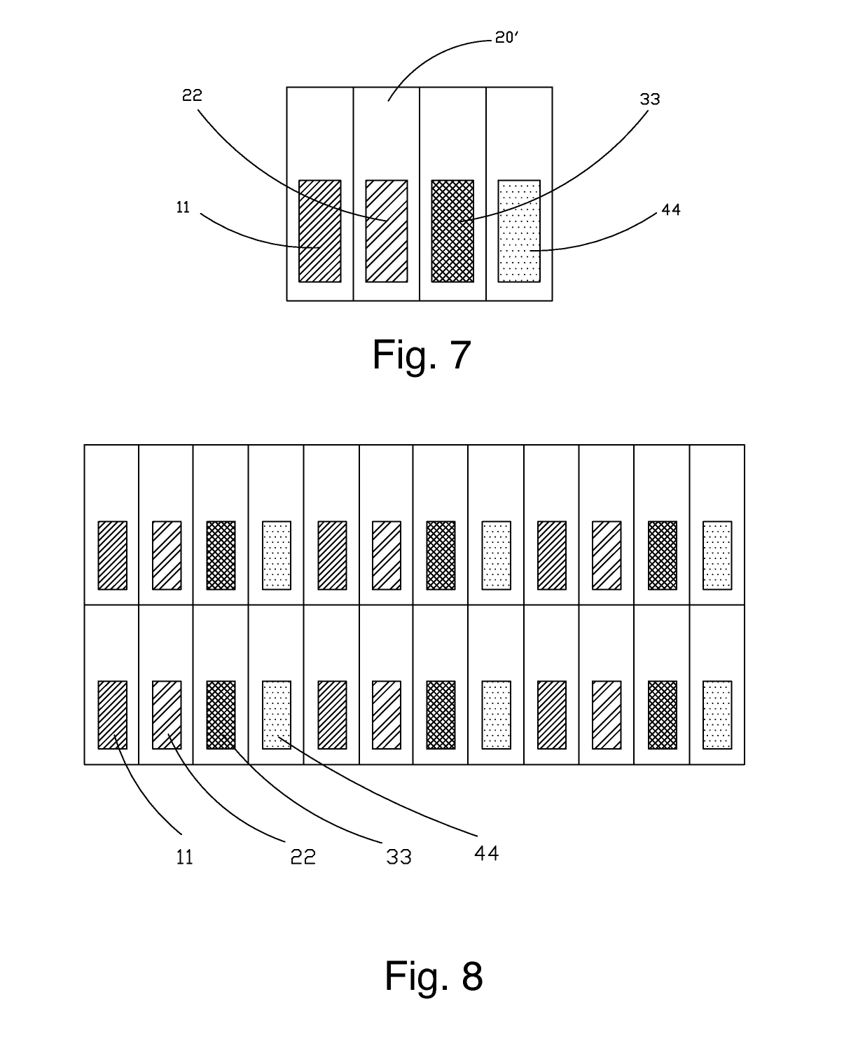

Please refer to FIGS. 6-7, which are the second embodiment of the present invention. Compared to the first embodiment shown in FIG. 1, the difference is that the OLED pixel structure 20′ further comprises a white sub-pixel 44, which has a white light emission layer 64.

The white light emission layer 64 comprises inorganic quantum dots, and the inorganic quantum dots are white light quantum dots, or the inorganic quantum dots are combinations of a red light quantum dot, a green light quantum dot and the blue light quantum dot, or the inorganic quantum dots are combinations of the blue light quantum dot and a yellow light quantum dot.

The white light quantum dots are quantum dots of II˜VI families comprising CdSe, CdS, CdTe, CdMnS, ZnSe or ZnMnSe, the blue light quantum dot is ZnCdS, CdSe/ZnS or nano-SiN₄, the green light quantum dot is CdSe/ZnS or ZnSe: Cu²⁺, the red light quantum dot is CdSe/CdS/ZnS, the yellow light quantum dot is CdSe/CdS/ZnS, or ZnS: Mn²⁺.

The material of the white light emission layer 64 could further comprise a white light organic host material.

In the embodiment, the OLED pixel structure 20′ further comprises a substrate 1 and a covering layer 9 sealing-connected to the substrate 1. The red, green, blue and white sub-pixel 11, 22, 33, and 44 are set on the substrate 1 respectively in one line, and are covered by the covering layer 9. The white sub-pixel 44 comprises: the anode 2 disposed on the substrate 1, the thin film transistor 3 disposed on the anode 2, the hole injection layer 4 disposed on the thin film transistor 3, the hole transport layer 5, disposed on the hole injection layer 4, the white light emission layer 64 disposed on the hole transport layer 5, the electron transport layer 7, disposed on the white light emission layer 64, and the cathode 8 disposed on the electron transport layer 7. The material of the electron transport layer 7, is 8-hydroxyquinoline aluminum salt, the material of the hole transport layer 5, is polytriphenylamine, and the material of the hole injection layer 4 is PEDOT (poly(3, 4-ethylene-dioxythiophene)).

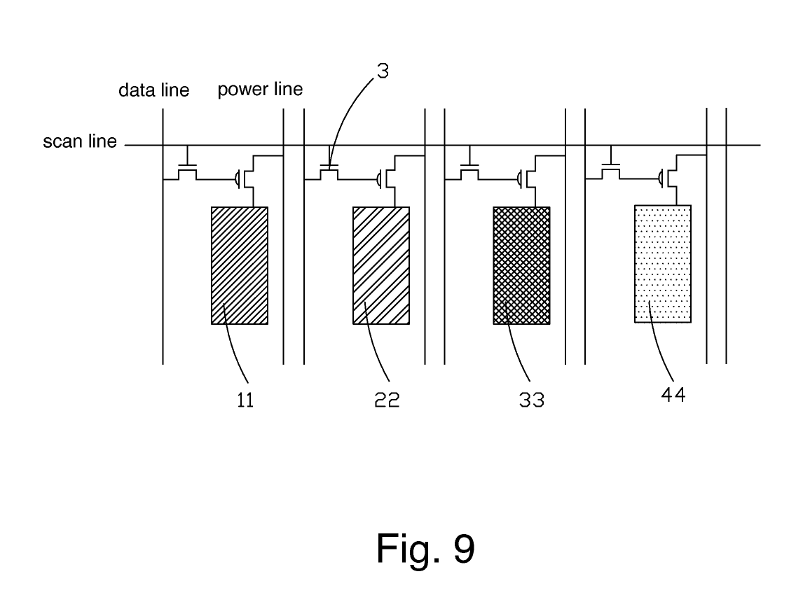

Please refer to FIG. 8, which is a structural schematic diagram of the display panel in which the pixel structure of the second embodiment is applied. As shown in FIG. 9, the red sub-pixel 11, green sub-pixel 22, blue sub-pixel 33, and the white sub-pixel 44 are driven by the TFT 3.

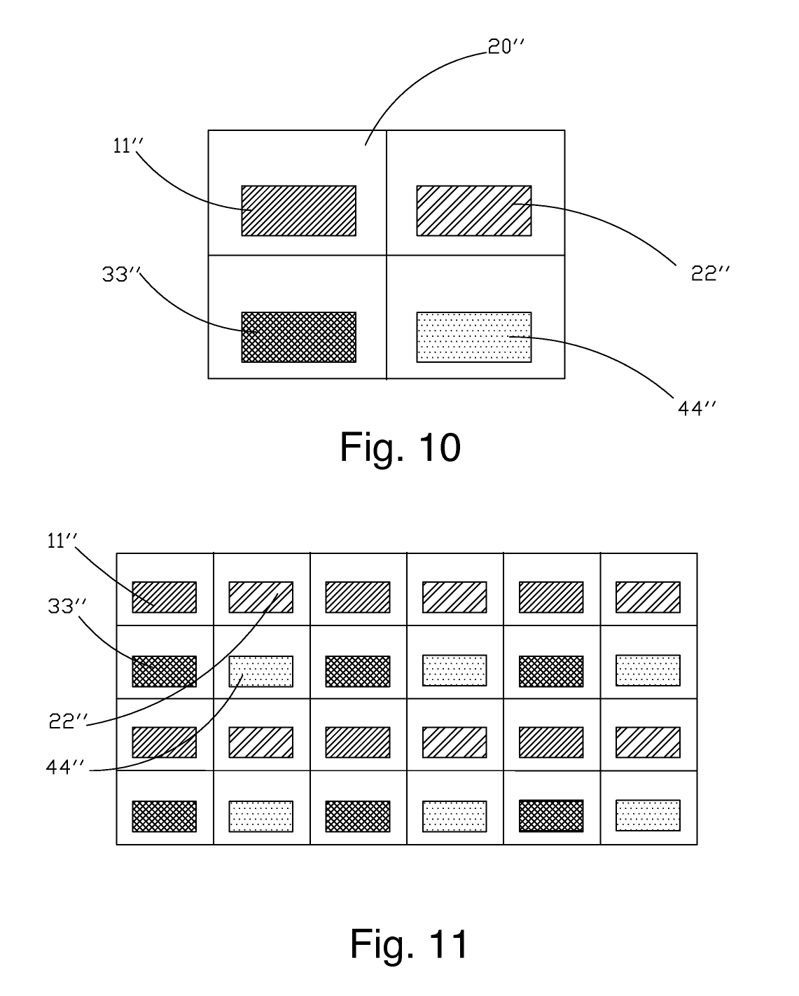

Please refer to FIG. 10 to FIG. 11, the schematic diagram of the OLED pixel structure 20″ of the third embodiment of the present invention is different from the second embodiment in that the red sub-pixel 11″, the green sub-pixel 22″, the blue sub-pixel 33″ and the white sub-pixel 44″ are aligned into two lines.

In summary, by using blue light quantum dot as the material of the blue light emission layer of the blue sub-pixel, the OLED pixel structure makes the blue sub-pixel to be more stable and have longer life time such that the whole OLED device is more stable and has longer life time. At the same time, the driving voltage of the blue sub-pixel could be lowered properly because the efficiency of the blue light quantum dot is higher. The OLED pixel structure could further comprise a white sub-pixel having a white light emission layer of which the material comprises inorganic quantum dot. The brightness of the OLED device can be improved by increasing the white sub-pixel.

Those with ordinary skill in the field can make other modifications or variations corresponding to the technical solution and technical idea of the present invention according to those mentioned above. All these modifications and variations should be covered by the protection scope of the Claims of the present invention.

What is claimed is:

1. An OLED pixel structure, comprising: a red, a green and a blue sub-pixel; wherein the red sub-pixel has a red light emission layer, the green sub-pixel has a green light emission layer, and the blue sub-pixel has a blue light emission layer and a material of the blue light emission layer comprises a blue light quantum dot.

2. The OLED pixel structure according to claim 1, further comprising a white sub-pixel having a white light emission layer.

3. The OLED pixel structure according to claim 2, wherein the material of the white light emission layer comprises a plurality of inorganic quantum dots, the inorganic quantum dots are a plurality of white light quantum dots, or the inorganic quantum dots are combinations of a red light quantum dot, a green light quantum dot and the blue light quantum dot, or the inorganic quantum dots are combinations of the blue light quantum dot and a yellow light quantum dot.

4. The OLED pixel structure according to claim 3, wherein the material of the white light emission layer further comprises white light organic host material.

5. The OLED pixel structure according to claim 3, wherein the white light quantum dots are quantum dots of II˜VI families comprising CdSe, CdS, CdTe, CdMnS, ZnSe or ZnMnSe, the blue light quantum dot is ZnCdS, CdSe/ZnS or nano-SiN₄, the green light quantum dot is CdSe/ZnS or ZnSe: Cu²⁺, the red light quantum dot is CdSe/CdS/ZnS, the yellow light quantum dot is CdSe/CdS/ZnS, or ZnS: Mn²⁺.

6. The OLED pixel structure according to claim 1, wherein the material of the blue light emission layer further comprises a blue light organic host material, and the blue light organic host material, a particle of the blue light quantum dot, and a solvent are mixed, and then coated and volatized to remove the solvent and obtain the blue light quantum dot; the solvent is chloroform, toluene, chlorobenzene, or methanol.

7. The OLED pixel structure according to claim 6, wherein the blue light organic host material is TCTA or TRZ.

8. The OLED pixel structure according to claim 1, wherein the blue light quantum dot, a surface coating reagent and a solvent are mixed, and then coated and volatizedto remove the solvent and obtain the blue light quantum dot; wherein the surface coating reagent comprises stearic acid, trioctylphosphine oxide, or polymethyl methacrylate, the solvent is chloroform, toluene, chlorobenzene, or methanol.

9. The OLED pixel structure according to claim 1, wherein the blue light quantum dot is ZnCdS, CdSe/ZnS, or nano-SiN₄.

10. The OLED pixel structure according to claim 1, wherein the red light emission layer is formed by a red light organic light emitting material, which is Ir(piq)₃; the green light emission layer is formed by a green light organic light emitting material, which is Ir(ppy)₃.

11. The OLED pixel structure according to claim 1, further comprising a substrate and a covering layer sealing-connected to the substrate; the red, green and blue sub-pixel are set on the substrate respectively and are covered by the covering layer; the material of the substrate and the covering layer is glass or soft material, and at least one of the substrate and the covering layer is pervious to light; the red sub-pixel comprises: an anode disposed on the substrate, a thin film transistor disposed on the anode, a hole injection layer disposed on the thin film transistor, a hole transport layer disposed on the hole injection layer, the red light emission layer disposed on the hole transport layer, an electron transport layer disposed on the red light emission layer, and a cathode disposed on the electron transport layer; the green sub-pixel comprises: the anode disposed on the substrate, the thin film transistor disposed on the anode, the hole injection layer disposed on the thin film transistor, the hole transport layer disposed on the hole injection layer, the green light emission layer disposed on the hole transport layer, the electron transport layer disposed on the green light emission layer, and the cathode disposed on the electron transport layer; the blue sub-pixel comprises: the anode disposed on the substrate, the thin film transistor disposed on the anode, the hole injection layer disposed on the thin film transistor, the hole transport layer disposed on the hole injection layer, the blue light emission layer disposed on the hole transport layer, the electron transport layer disposed on the green light emission layer, and the cathode disposed on the electron transport layer; the material of the electron transport layer is 8-hydroxyquinoline aluminum salt, the material of the hole transport layer is polytriphenylamine, and the material of the hole injection layer is PEDOT.

12. The OLED pixel structure according to claim 2, further comprising a substrate and a covering layer sealing-connected to the substrate; the red, green, blue and white sub-pixel are set on the substrate respectively and are covered by the covering layer; the white sub-pixel comprises: an anode disposed on the substrate, a thin film transistor disposed on the anode, a hole injection layer disposed on the thin film transistor, a hole transport layer disposed on the hole injection layer, the white light emission layer disposed on the hole transport layer, an electron transport layer disposed on the white light emission layer, and a cathode disposed on the electron transport layer; the material of the electron transport layer is 8-hydroxyquinoline aluminum salt, the material of the hole transport layer is polytriphenylamine, and the material of the hole injection layer is PEDOT.

13. The OLED pixel structure according to claim 1, wherein the red light emission layer and the green light emission layer are manufactured by vacuum evaporation and formed after forming the blue light emission layer.

14. An OLED pixel structure, comprising: a red, a green and a blue sub-pixel; wherein the red sub-pixel has a red light emission layer, the green sub-pixel has a green light emission layer, and the blue sub-pixel has a blue light emission layer and a material of the blue light emission layer comprises a blue light quantum dot;
wherein the material of the blue light emission layer further comprises a blue light organic host material, and the blue light organic host material, a particle of the blue light quantum dot, and a solvent are mixed, and then coated and volatizedto remove the solvent and obtain the blue light quantum dot; the solvent is chloroform, toluene, chlorobenzene, or methanol;
wherein the blue light organic host material is TCTA or TRZ;
wherein the blue light quantum dot, a surface coating reagent and a solvent are mixed, and then coated and volatizedto remove the solvent and obtain the blue light quantum dot; wherein the surface coating reagent comprises stearic acid, trioctylphosphine oxide, or polymethyl methacrylate, the solvent is chloroform, toluene, chlorobenzene, or methanol;
wherein the blue light quantum dot is ZnCdS, CdSe/ZnS, or nano-SiN₄;
wherein the red light emission layer is formed by a red light organic light emitting material, which is Ir(piq)₃; the green light emission layer is formed by a green light organic light emitting material, which is Ir(ppy)₃;
wherein the OLED pixel structure further comprises a substrate and a covering layer sealing-connected to the substrate; the red, green and blue sub-pixel are set on the substrate respectively and are covered by the covering layer; the material of the substrate and the covering layer is glass or soft material, and at least one of the substrate and the covering layer is pervious to light; the red sub-pixel comprises: an anode disposed on the substrate, a thin film transistor disposed on the anode, a hole injection layer disposed on the thin film transistor, a hole transport layer disposed on the hole injection layer, the red light emission layer disposed on the hole transport layer, an electron transport layer disposed on the red light emission layer, and a cathode disposed on the electron transport layer; the green sub-pixel comprises: the anode disposed on the substrate, the thin film transistor disposed on the anode, the hole injection layer disposed on the thin film transistor, the hole transport layer disposed on the hole injection layer, the green light emission layer disposed on the hole transport layer, the electron transport layer disposed on the green light emission layer, and the cathode disposed on the electron transport layer; the blue sub-pixel comprises: the anode disposed on the substrate, the thin film transistor disposed on the anode, the hole injection layer disposed on the thin film transistor, the hole transport layer disposed on the hole injection layer, the blue light emission layer disposed on the hole transport layer, the electron transport layer disposed on the green light emission layer, and the cathode disposed on the electron transport layer; the material of the electron transport layer is 8-hydroxyquinoline aluminum salt, the material of the hole transport layer is polytriphenylamine, and the material of the hole injection layer is PEDOT;
wherein the red light emission layer and the green light emission layer are manufactured by vacuum evaporation and formed after forming the blue light emission layer.
